(19) United States
(12) Patent Application Publication
(10) Pub. No.: US 2026/0292975 A1
(43) Pub. Date: Sep. 24, 2026

(54) METHOD FOR MANUFACTURING WIRING BOARD, METHOD FOR MANUFACTURING SEMICONDUCTOR DEVICE, WIRING BOARD, AND SEMICONDUCTOR DEVICE

(71) Applicant: Resonac Corporation, Minato-ku, Tokyo (JP)

(72) Inventors: Kazue HIRANO, Tokyo (JP); Hirokazu NOMA, Tokyo (JP)

(21) Appl. No.: 19/476,185

(22) PCT Filed: Jul. 13, 2023
(86) PCT No.: PCT/JP2023/025947

§ 371 Date: Oct. 17, 2025

(51) Int. Cl. H05K 1/02; H05K 3/10

(52) U.S. Cl. CPC H05K 1/0296; H05K 3/103; H05K 2201/10204

(57) ABSTRACT

A method for manufacturing a wiring board includes forming a first insulation layer on a support substrate, forming a resist layer on the first insulation layer, forming a plurality of openings including first and second openings for wiring electrodes and a third opening for a dummy electrode in the resist layer, forming first and second wiring electrodes in the first and second openings, respectively, forming a first dummy electrode in the third opening, removing the resist layer after forming the first and second wiring electrodes and the first dummy electrode, and forming a second insulation layer on the first insulation layer so as to cover at least the first dummy electrode. In the manufacturing method, surfaces of the first and second wiring electrodes are exposed from the second insulation layer, and at least a part of the first dummy electrode is located between the first and second wiring electrodes.

### TECHNICAL FIELD

The present disclosure relates to a method for manufacturing a wiring board, a method for manufacturing a semiconductor device, the wiring board, and the semiconductor device.

### BACKGROUND ART

For the purpose of increasing the density and performance of semiconductor packages, an implementation configuration in which semiconductor elements (hereinafter also referred to as “chips”) having different performances are mounted together in a single package has been proposed. In terms of cost, the importance of high-density interconnect technology between chips is increasing (see, for example, Patent Literature 1). Furthermore, a connection method referred to as package-on-package is widely adopted in smartphones and tablet terminals. The package-on-package is a method for connecting different packages on a package by flip-chip mounting (See, for example, Non Patent Literatures 1 and 2). As a form for mounting at a higher density, a package technology (organic interposer) using an organic substrate having high density wiring, a fan-out type package technology (FO-WLP) having a through mold via (TMV), a package technology using silicon or glass interposer, a package technology using a through-silicon via (TSV), a package technology using a chip embedded in a substrate for inter-chip transmission, and the like have been proposed. Particularly, in the organic interposer and the FO-WLP, in a case where semiconductor chips are mounted in parallel, a fine wiring layer is required in order to achieve high-density electrical conduction (see Patent Literature 2).

In addition to the above-described fine pitching, in recent years, semiconductor devices have been widely used in severe environments for in-vehicle applications. Therefore, there is an increasing demand for high reliability such as improvement in heat resistance and crack resistance for a permanent coating such as solder resist used for a semiconductor device. When a temperature change is applied to a semiconductor device in which a semiconductor device is mounted on a printed wiring board, due to a difference in thermal expansion coefficients of various materials, for example, cracks may occur in a joint portion with the external connection terminal of the substrate, which causes disconnection. (See Patent Literature 3)

### CITATION LIST

### Patent Literature

Patent Literature 1: Japanese Unexamined Patent Publication No. 2011-029287
Patent Literature 2: U.S. Patent Application Publication No. 2011/0221071
Patent Literature 3: Japanese Unexamined Patent Publication No. 2017-157666

### Non Patent Literature

Non Patent Literature 1: Application of Through Mold Via (TMV) as PoP Base Package, Electronic Components and Technology Conference (ECTC), 2008
Non Patent Literature 2: Advanced Low Profile POP Solution with Embedded Wafer Level POP (eWLB-POP) Technology, ECTC, 2012

### SUMMARY OF INVENTION

### Technical Problem

In various conventional semiconductor devices, cracks may occur in a resin composition as a constituent material due to a rapid or continuous temperature change. When such cracks occur, the wiring in the semiconductor device may be fractured due to the cracks. Therefore, it is desired to prevent breakage of wiring due to the cracks.

An object of the present disclosure is to provide a method for manufacturing a wiring board, a method for manufacturing a semiconductor device, the wiring board, and the semiconductor device, which can prevent breakage of wiring due to cracks.

### Solution to Problem

[1] As one aspect, the present disclosure provides a method for manufacturing a wiring board. The method for manufacturing a wiring board includes forming a first insulation layer on a support substrate, forming a resist layer on the first insulation layer, forming a plurality of openings including a first opening and second opening for a wiring electrode and a third opening for a dummy electrode in the resist layer, forming a first wiring electrode and a second wiring electrode in the first opening and the second opening, respectively, forming a first dummy electrode in the third opening, removing the resist layer after forming the first wiring electrode, the second wiring electrode, and the first dummy electrode, and forming a second insulation layer on the first insulation layer so as to cover at least the first dummy electrode. In the manufacturing method, surfaces of the first wiring electrode and the second wiring electrode are exposed from the second insulation layer, and at least a part of the first dummy electrode is located between the first wiring electrode and the second wiring electrode.

According to the study conducted by the present inventors, cracks occurring in the second insulation layer and the like often occur in the vicinity of the wiring electrodes connected to a semiconductor device and the like via an exposed surface, but it is found that the occurrence of cracks or the extension of cracks that occur can be suppressed by providing the dummy electrode close to these wiring electrodes. In the method for manufacturing this wiring board, at least a part of the first dummy electrode not connected to the semiconductor chip or the like is located between the first wiring electrode and the second wiring electrode, which are connected to the semiconductor chip or the like. Thus, in the wiring board manufactured by this manufacturing method, it is possible to suppress the occurrence of cracks in the second insulation layer or to suppress the extension of the cracks that occur. As a result, when the semiconductor device is manufactured using the wiring board, the wiring of the first wiring electrode or the second wiring electrode is prevented from being fractured due to a temperature change. As described above, in the method for manufacturing this wiring board, it is possible to provide a wiring board in which the breakage of wiring due to cracks is prevented.
[2] In the method for manufacturing a wiring board according to [1], a width of the first dummy electrode may be equal to or more than 10 μm in a direction extending outward from a center of the first wiring electrode. In this case, the first dummy electrode can reliably suppress the extension of the cracks occurring in the insulation layer in the vicinity of the first wiring electrode or the second wiring electrode. Thus, it is possible to provide a wiring board that more reliably prevents breakage of the wiring due to the cracks.
[3] In the method for manufacturing a wiring board according to [1] or [2], the first dummy electrode may have a portion having a maximum width of 100 μm or more in a direction extending outward from a center of the first wiring electrode. In this case, the occurrence of cracks in the insulation layer in the vicinity of the first wiring electrode or the second wiring electrode can be reliably suppressed, or the extension of the cracks that occur can be more reliably suppressed. Thus, it is possible to provide a wiring board that more reliably prevents breakage of the wiring due to the cracks.
[4] In the method for manufacturing a wiring board according to any one of [1] to [3], a distance between the first wiring electrode and the first dummy electrode may be equal to or more than 50 μm. In this case, insulation between the first wiring electrode and the first dummy electrode can be ensured. Thus, it is possible to provide a wiring board in which the first dummy electrode does not interfere with the conduction performance of the first wiring electrode.
[5] In the method for manufacturing a wiring board according to any one of [1] to [4], in the forming a plurality of openings in the resist layer, a fourth opening for a dummy electrode may be further formed, and this manufacturing method may further include forming a second dummy electrode in the fourth opening. At least a part of each of the first dummy electrode and the second dummy electrode may be formed between the first wiring electrode and the second wiring electrode, the first dummy electrode may be located on the first wiring electrode side, and the second dummy electrode may be located on the second wiring electrode side. In this case, the occurrence of cracks in the vicinity of the second wiring electrode or the extension of the cracks that occur in the vicinity of the second wiring electrode can be suppressed by providing the first dummy electrode and the second dummy electrode. Thus, it is possible to provide a wiring board that further suppresses breakage of the wiring due to the cracks.
[6] The method for manufacturing a wiring board according to [5] may further include forming a wiring portion between the first dummy electrode and the second dummy electrode, and the wiring portion may include a plurality of wirings of 10 μm or less. In this case, it is possible to provide a wiring board in which a desired wiring is formed between the first wiring electrode and the second wiring electrode.
[7] In the method for manufacturing a wiring board according to [5] or [6], the first dummy electrode and the second dummy electrode may be connected by a conductive material. In this case, the strength of the first dummy electrode and the second dummy electrode can be improved to provide a wiring board that more reliably suppresses the occurrence of cracks in the vicinity of the first wiring electrode and the second wiring electrode.
[8] In the method for manufacturing a wiring board according to any one of [1] to [7], the first dummy electrode may be formed so as to surround the first wiring electrode when viewed in plan. In this case, it is possible to provide a wiring board in which the occurrence of cracks or the extension of cracks is suppressed in any direction in the vicinity of the first wiring electrode. Furthermore, by providing the dummy electrode so as to surround the wiring electrode, it is possible to provide a wiring board having an arrangement that does not interfere with improvement in the mounting density of the wiring electrode. Note that the second dummy electrode may be formed so as to surround the second wiring electrode when viewed in plan. In this case as well, the same effects as those of the first dummy electrode can be obtained.
[9] In the method for manufacturing a wiring board according to any one of [1] to [8], the first wiring electrode may have a curved portion when viewed in plan, and the first dummy electrode may have a curved portion when viewed in plan. Since the first wiring electrode has the curved portion, it is possible to provide a wiring board in which the occurrence of cracks starting from the vicinity of the first wiring electrode is suppressed. Furthermore, since the first dummy electrode has the curved portion, it is possible to provide a wiring board in which the force of the cracks that occur is dispersed and further extension of the cracks is suppressed.
[10] In the method for manufacturing a wiring board according to any one of [1] to [9], the first dummy electrode may have a thickness that is half or more of the thickness of the second insulation layer. In this case, it is possible to provide a wiring board in which the extension of the cracks starting from the vicinity of the first wiring electrode or the second wiring electrode is reliably suppressed by the first dummy electrode. Note that the second dummy electrode may have a thickness of half or more of the thickness of the second insulation layer. In this case as well, the same effects as those of the first dummy electrode can be obtained.
[11] As another aspect, the present disclosure provides a method for manufacturing a semiconductor device. The method for manufacturing this semiconductor device includes preparing the wiring board manufactured by the method for manufacturing a wiring board according to any one of [1] to [10] and mounting a semiconductor chip on the wiring board using a conductive member.

In the method for manufacturing this semiconductor device, as described above, in the wiring board on which the semiconductor chip is mounted, it is possible to provide a semiconductor device in which the occurrence of cracks starting from the vicinity of the first wiring electrode and the second wiring electrode is suppressed or the extension of the cracks that occur is suppressed. Thus, it is possible to provide a semiconductor device in which breakage of wiring due to cracks is prevented.
[12] In the method for manufacturing a semiconductor device according to [11], in the mounting the semiconductor chip, a first conductive member and a second conductive member, which are the conductive member, may be disposed on the first wiring electrode and second wiring electrode of the wiring board, respectively, the semiconductor chip may be mounted on the first conductive member and the second conductive member, connection terminals of the semiconductor chip may be connected to the first wiring electrode and the second wiring electrode via the first conductive member and the second conductive member, and the semiconductor chip may be mounted on a surface of the wiring board on which the first dummy electrode is formed.
[13] As still another aspect, the present disclosure provides a wiring board. This wiring board includes a support substrate, a first insulation layer placed on the support substrate, a second insulation layer placed on the first insulation layer, a first wiring electrode and second wiring electrode placed in the second insulation layer, and a first dummy electrode placed in the second insulation layer. Surfaces of the first wiring electrode and the second wiring electrode are exposed from the second insulation layer, and at least a part of the first dummy electrode is located between the first wiring electrode and the second wiring electrode.

In this wiring board, at least a part of the first dummy electrode not connected to the semiconductor chip or the like is located between the first wiring electrode and the second wiring electrode, which are connected to the semiconductor chip or the like. In this case, even when a temperature change or the like occurs in a semiconductor device that uses this wiring board, the occurrence of cracks in the second insulation layer or the like can be suppressed, or the extension of the cracks that occur can be suppressed. As a result, in the semiconductor device that uses the wiring board, the wiring of the first wiring electrode or the second wiring electrode is prevented from being fractured due to the temperature change.
[14] In the wiring board according to [13], a width of the first dummy electrode may be equal to or more than 10 μm in a direction extending outward from a center of the first wiring electrode. In this case, the first dummy electrode can reliably suppress the extension of the cracks occurring in the insulation layer in the vicinity of the first wiring electrode or the second wiring electrode. Thus, it is possible to more reliably prevent breakage of the wiring due to the cracks.
[15] The wiring board according to [13] or [14] may further include a second dummy electrode placed in the second insulation layer, at least a part of each of the first dummy electrode and the second dummy electrode may be located between the first wiring electrode and the second wiring electrode, the first dummy electrode may be located on the first wiring electrode side, and the second dummy electrode may be located on the second wiring electrode side. In this case, the occurrence of cracks in the vicinity of the second wiring electrode or the extension of the cracks that occur in the vicinity of the second wiring electrode can be suppressed by providing the second dummy electrode. As described above, in the wiring board, it is possible to more reliably prevent breakage of the wiring due to the cracks.
[16] In the wiring board according to any one of [13] to [15], the first dummy electrode may be formed so as to surround the first wiring electrode when viewed in plan. In this case, it is possible to suppress the occurrence of cracks or the extension of cracks in any direction in the vicinity of the first wiring electrode. Furthermore, by providing the dummy electrode so as to surround the wiring electrode, it is possible to provide a wiring board having an arrangement that does not interfere with improvement in the mounting density of the wiring electrode. Note that the second dummy electrode may be formed so as to surround the second wiring electrode when viewed in plan.
[17] As still another aspect, the present disclosure provides a semiconductor device. This semiconductor device includes the wiring board according to any one of [13] to [16], a first conductive portion and second conductive portion placed on the wiring board and on the first wiring electrode and the second wiring electrode, respectively, and a semiconductor chip mounted on the second insulation layer so as to be electrically connected to the first conductive portion and the second conductive portion. In this case, as described above, it is possible to prevent breakage of the wiring due to the cracks.

### Advantageous Effects of Invention

According to the present disclosure, it is possible to prevent breakage of the wiring due to the cracks.

### BRIEF DESCRIPTION OF DRAWINGS

FIG. 1 is a cross-sectional view illustrating an example of a semiconductor device in which a semiconductor chip is mounted on a wiring board.

FIG. 2 is a plan view illustrating an upper surface side of a wiring board of the semiconductor device illustrated in FIG. 1.

FIG. 3 is a view illustrating a method for manufacturing a wiring board constituting the semiconductor device illustrated in FIG. 1.

FIG. 4 is a view illustrating a method for manufacturing a wiring board, and illustrates steps following FIG. 3.

FIG. 5 is a view illustrating a method for manufacturing a wiring board, and illustrates steps following FIG. 4.

FIG. 6 is a view illustrating a method for manufacturing the semiconductor device illustrated in FIG. 1.

FIG. 7 is a view illustrating a state in which extension of cracks occurring in a wiring board (semiconductor device) is stopped by a dummy electrode.

FIG. 8 is an enlarged view of a portion VIII in FIG. 7.

### DESCRIPTION OF EMBODIMENTS

Hereinafter, an embodiment according to the present invention will be described in detail with reference to the drawings. In the following description, the same or corresponding parts will be denoted by the same reference numerals, and redundant description thereof will be omitted. Furthermore, unless otherwise specified, the positional relationship such as up, down, left, and right is based on the positional relationship shown in the drawings. The use of the terms “left”, “right”, “front”, “back”, “up”, “down”, “above”, “below”, and the like in the description and claims of this specification is intended for description and is not necessarily meant to indicate a permanent relative position thereof. Furthermore, dimensional ratios in the drawings are not limited to the illustrated ratios.

In the present specification, the term “layer” includes a structure having a shape partially formed in addition to a structure having a shape formed on the entire surface when observed as a plan view. In the present specification, the term “step” includes not only an independent step but also a step that cannot be clearly distinguished from other steps as long as an intended action of the step is achieved. In the present specification, a numerical range indicated using “A to B” indicates a range including numerical values A and B described before and after “to” as a minimum value and a maximum value, respectively.

### (Example of Semiconductor Device Including Wiring Board)

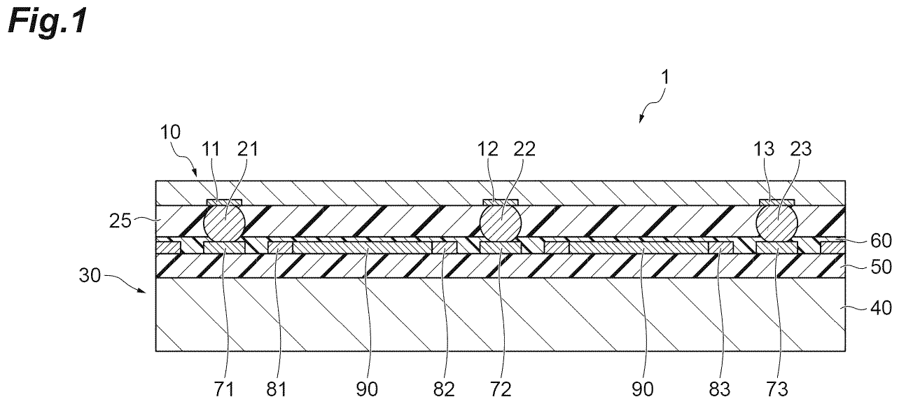

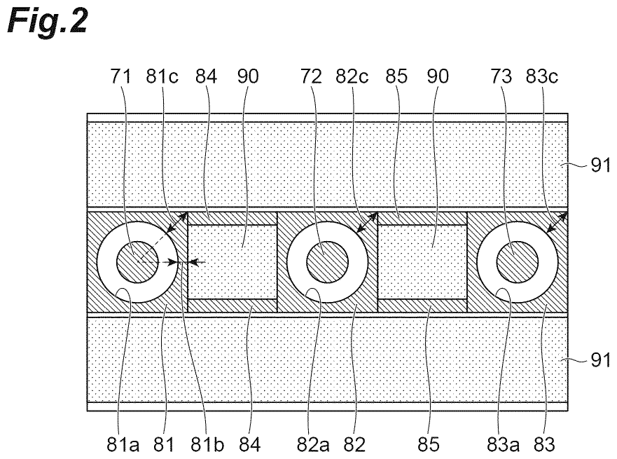

An example of a semiconductor device including a wiring board will be described with reference to FIGS. 1 and 2. As illustrated in FIG. 1, a semiconductor device 1 includes a semiconductor chip 10, solder bumps 21, 22, and 23 (a first conductive portion and a second conductive portion), an insulation resin layer 25, and a wiring board 30.

The semiconductor chip 10 is, for example, a logic IC or a memory IC, and is mounted on the wiring board 30 via the solder bumps 21 to 23. Respective connection terminals 11, 12, and 13 of the semiconductor chip 10 are connected to wiring electrodes 70 of the wiring board 30 via the solder bumps 21 to 23. The insulation resin layer 25 formed of an encapsulation resin such as an underfill material is provided between the semiconductor chip 10 and the wiring board 30.

As illustrated in FIGS. 1 and 2, the wiring board 30 includes a support substrate 40, a first insulation layer 50, a second insulation layer 60, wiring electrodes 71, 72, and 73 (a first wiring electrode and a second wiring electrode), and dummy electrodes 81, 82, and 83 (a first dummy electrode and a second dummy electrode). The wiring board 30 may further include a wiring portion 90. The wiring portion 90 is a portion provided with various types of wirings.

The support substrate 40 is not particularly limited, and is, for example, a silicon substrate, a glass substrate, an SUS substrate, a glass cloth-reinforced substrate, or an encapsulation resin embedding a semiconductor element. The thickness of the support substrate 40 is, for example, from 0.2 mm to 2.0 mm. When the thickness of the support substrate 40 is equal to or more than 0.2 mm, handleability can be improved when the wiring board 30 is manufactured or when the semiconductor device 1 is manufactured using the wiring board 30. When the thickness of the support substrate 40 is equal to or less than 2.0 mm, the material cost can be suppressed and the cost can be reduced.

The first insulation layer 50 is an insulation layer formed on the support substrate 40, and is formed of, for example, a photosensitive insulation material. In this case, the first insulation layer 50 is made of a cured product of the photosensitive insulation material. As the photosensitive insulation material to be used, a liquid or film-like material can be used. From the viewpoint of film thickness uniformity and cost, it is preferable to use a film-like photosensitive insulation material. Furthermore, from the viewpoint of forming fine wiring in the first insulation layer 50, the photosensitive insulation material to be used preferably contains fillers (filling material) having an average particle size of 500 nm or less in a photosensitive resin composition. The average particle size of the fillers is more preferably from 50 nm to 200 nm. The filler content in the photosensitive insulation material is preferably 0 to 70 parts by mass, and more preferably 10 to 50 parts by mass in a case where the mass of the photosensitive resin composition excluding the fillers is 100 parts by mass. Note that examples of a method for measuring the average particle size of the fillers include a method for measuring each particle size of about 20 filler particles using a scanning electron microscope (SEM). Examples of the measurement method using the SEM include a method in which a sample obtained by curing a resin composition containing fillers is prepared, a center portion of the sample is cut, and a cross-section thereof is observed with the SEM.

The thermal expansion coefficient of the first insulation layer 50 after curing is preferably equal to or less than 80×10⁻⁶/K from the viewpoint of suppressing warpage, and more preferably equal to or less than 70×10⁻⁶/K from the viewpoint of obtaining high reliability. The thermal expansion coefficient of the first insulation layer 50 after material curing is more preferably equal to or more than 20×10⁻⁶/K from the viewpoint of stress relaxation of the insulation material and obtaining a high-definition pattern.

The thickness of the first insulation layer 50 is not particularly limited, but is, for example, preferably equal to or less than 10 μm, more preferably equal to or less than 5 μm, and still more preferably equal to or less than 3 μm. When the thickness of the first insulation layer 50 is within the above-described range, fine wiring is easily formed in the first insulation layer 50. Note that the thickness of the first insulation layer 50 is preferably equal to or more than 1 μm from the viewpoint of insulation reliability.

The second insulation layer 60 is an insulation layer formed on the first insulation layer 50. Similarly to the first insulation layer 50, the second insulation layer 60 is formed of, for example, a photosensitive insulation material, and is made of a cured product of the photosensitive insulation material. Other configurations (thickness, filler content, and the like) of the second insulation layer 60 may be the same as those of the first insulation layer 50.

The wiring electrodes 71 to 73 are wiring electrodes exposed to the front surface side of the wiring board 30, and are electrodes for being connected to the semiconductor chip 10. The wiring electrodes 71 to 73 are formed on the first insulation layer 50 and in the second insulation layer 60. Each of the wiring electrodes 71 to 73 has, for example, a circular or rectangular shape when viewed in plan. In a case where the wiring electrodes 71 to 73 have circular shape, the diameter of each of the wiring electrodes 71 to 73 is, for example, from 50 μm to 300 μm. The wiring electrodes 71 to 73 are formed of, for example, a conductive material such as copper. For the wiring board 30, each of the wiring electrodes 71 to 73 is configured such that the surface thereof is exposed from the second insulation layer 60, and is connected to the semiconductor chip 10 via each of the solder bumps 21 to 23 respectively disposed on the wiring electrodes 71 to 73. Note that in the example illustrated in the drawings, three wiring electrodes 71 to 73 are illustrated in order to facilitate the description, but the wiring electrodes in the wiring board 30 are not limited thereto, and a larger number of wiring electrodes may be provided in one wiring board 30. The same applies to dummy electrodes 81 to 83 to be described later.

The dummy electrodes 81 to 83 and the wiring electrodes 71 to 73 are formed on the first insulation layer 50 and in the second insulation layer 60. At least a part of each of the dummy electrodes 81 to 83 is located between two of the wiring electrodes 71 to 73 (between the wiring electrodes 71 and 72 or between the wiring electrodes 72 and 73) that are adjacent to each other. The dummy electrodes 81 to 83 are formed so as to respectively surround the corresponding wiring electrodes 71 to 73 when viewed in plan. In the example illustrated in FIG. 2, each of the dummy electrodes 81 to 83 has circular vacant regions 81a, 82a, and 83a inside, and has a frame-like (peripheral) outer shape having a rectangular shape. The corresponding wiring electrodes 71 to 73 are respectively disposed in the vacant regions 81a to 83a of the dummy electrodes 81 to 83. Since each of the dummy electrodes 81 to 83 has such a shape, the electrode arrangement in a planar direction of the wiring board 30 can be achieved efficiently, and the mounting density can be improved while providing the dummy electrodes 81 to 83. Similarly to the wiring electrodes 71 to 73, the dummy electrodes 81 to 83 are made of, for example, copper. Each of the dummy electrodes 81 to 83 is configured to be encapsulated in the second insulation layer 60, and is an electrode that is not connected to the semiconductor chip 10 via a solder bump or the like, unlike the wiring electrodes 71 to 73.

Each of the dummy electrodes 81 to 83 has a width of, for example, 10 μm or more in the narrowest portion 81b in a direction extending outward from the center of each of the corresponding wiring electrodes 71 to 73. The width of the narrowest portion 81b is preferably equal to or more than 20 μm. Furthermore, each of the dummy electrodes 81 to 83 has a width (maximum width) of, for example, 100 μm or more in the widest portion 81c in a direction extending outward from the center of each of the corresponding wiring electrodes 71 to 73. The width of the widest portion 81c is preferably equal to or more than 150 μm. Note that a distance between the outer periphery of each of the wiring electrodes 71 to 73 and the inner periphery of each of the dummy electrodes 81 to 83 is, for example, equal to or more than 50 μm, preferably equal to or more than 100 μm.

A connection electrode 84 and a connection electrode 85 may be further provided between the dummy electrodes 81 and 82 and between the dummy electrodes 82 and 83, respectively. The connection electrode 84 is an electrode extending so as to connect the dummy electrodes 81 and 82. The connection electrode 85 is an electrode extending so as to connect the dummy electrodes 82 and 83. Similarly to the wiring electrodes 71 to 73 and the dummy electrodes 81 to 83, the connection electrodes 84 and 85 can be formed of copper wiring.

The wiring portions 90 may be further provided between the connection electrodes 84 and between the connection electrodes 85. The wiring portion 90 is a wiring portion including fine wiring (for example, wiring of 10 μm or less). Furthermore, another wiring portions 91 may be provided outside the dummy electrodes 81 to 83 (between other dummy electrodes adjacent in the vertical direction in the drawing). Similarly to the wiring portion 90, the wiring portion 91 is a wiring portion including a plurality of fine wirings. The wiring portions 90 and 91 may not be provided, and in that case, the wiring electrodes 71 to 73 and the dummy electrodes 81 to 83 may be further provided at the arrangement positions of the wiring portions 90 and 91.

### (Method for Manufacturing Wiring Board)

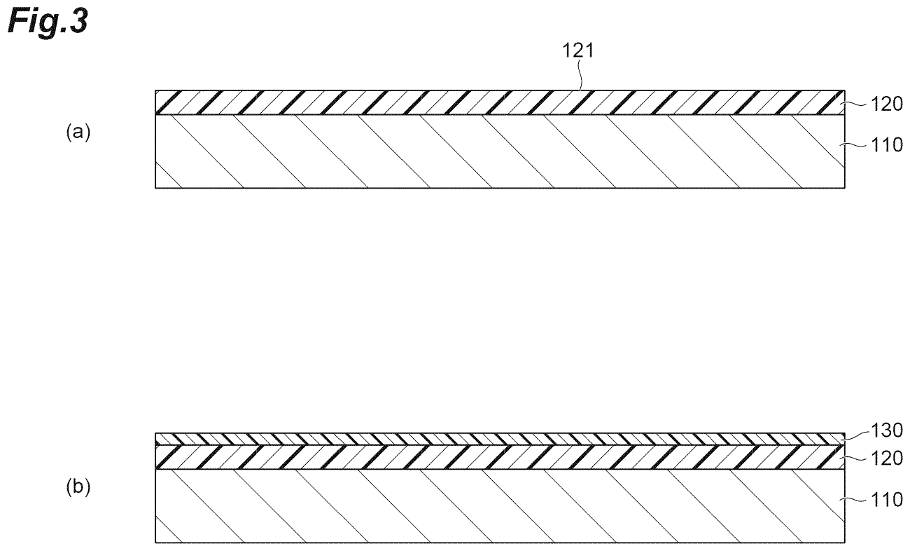

Next, a method for manufacturing the wiring board 30 will be described with reference to FIGS. 3 to 5. FIGS. 3 to 5 are views sequentially illustrating a method for manufacturing one or a plurality of wiring boards 30. The method for manufacturing the wiring board 30 includes the following steps (a) to (h).
(a) A step of forming a first insulation layer on a support substrate.
(b) A step of forming a seed layer on the first insulation layer.
(c) A step of forming a resist layer on the first insulation layer (seed layer).
(d) A step of forming an opening for a wiring electrode and an opening for a dummy electrode in the resist layer.
(e) A step of forming a wiring electrode in the opening for the wiring electrode.
(f) A step of forming a dummy electrode in the opening for the dummy electrode.
(g) A step of removing the resist layer after forming the wiring electrode and the dummy electrode.
(h) A step of forming a second insulation layer on the first insulation layer so as to cover the dummy electrode.

The method for manufacturing a wiring board according to the present embodiment is particularly suitable in a form in which miniaturization and multiple pins are required, and is particularly suitable in a package form in which an interposer for mix-mounting different types of chips is required. More specifically, the manufacturing method according to the present embodiment is suitable in a package form in which an interval between the pins is equal to or less than 200 μm (for example, 30 μm to 100 μm in the case of finer pins), and the number of pins is equal to or more than 500 (for example, 1000 to 10000 pins in the case of finer pins). Note that the pin here means a wiring electrode.

[Step (a)]

In step (a), first, as illustrated in (a) of FIG. 3, a support substrate 110 is prepared, and a first insulation layer 120 is formed on the support substrate 110. The support substrate 110 is a substrate corresponding to the support substrate 40, which is not particularly limited, and is, for example, a silicon substrate, a glass substrate, an SUS substrate, a glass cloth-reinforced substrate, or an encapsulation resin embedding a semiconductor element. The thickness of the support substrate 110 may be, for example, from 0.2 mm to 2.0 mm. When the thickness of the support substrate 110 is equal to or more than 0.2 mm, the handleability can be improved. Furthermore, when the thickness of the support substrate 110 is equal to or less than 2.0 mm, the material cost can be suppressed and the cost can be reduced. The planar shape of the support substrate 140 may have a wafer shape or a panel shape. The size of the support substrate 110 is not particularly limited. However, for example, the support substrate 110 is preferably a wafer having a diameter of 200 mm, a diameter of 300 mm, or a diameter of 450 mm, or a rectangular panel having a side of 300 mm to 700 mm.

The first insulation layer 120 is formed of, for example, an insulation material containing at least one of a photosensitive insulation material or a thermosetting insulation resin composition. As the insulation material, a liquid or film-like material can be used, and a film-like insulation material is preferably used from the viewpoint of film thickness uniformity and cost. In a step of forming the first insulation layer 120, the first insulation layer 120 is formed by laminating such a film-like insulation material on the support substrate 110. Furthermore, in a case where fine wiring is formed in the first insulation layer 120, the insulation material preferably contains fillers (filling material) having an average particle size of 500 nm or less in a resin composition. The average particle size of the fillers is more preferably from 50 nm to 200 nm. The filler content in the insulation material is preferably 0 to 70 parts by mass, and more preferably 10 to 60 parts by mass in a case where the mass of the photosensitive resin composition excluding the fillers is 100 parts by mass.

In a case where the film-like insulation material is used as the first insulation layer 120, a lamination step is preferably performed at a low temperature, and thus an insulation film that can be laminated at 40° C. to 120° C. is preferably employed. When the temperature at which the film-like insulation material used as the first insulation layer 120 can be laminated is equal to or higher than 40° C., tackiness at room temperature (about 25° C.) can be weakened to improve handleability. On the other hand, in a case where the temperature at which the film-like insulation material used as the first insulation layer 120 can be laminated is equal to or lower than 120° C., warpage after lamination can be reduced when the insulation film is attached by lamination.

The first insulation layer 120 may be cured after the above-described film-like photosensitive material is laminated on the support substrate 110. The thermal expansion coefficient of the first insulation layer 120 after curing is preferably equal to or less than 80×10⁻⁶/K from the viewpoint of suppressing warpage, and more preferably equal to or less than 70×10⁻⁶/K from the viewpoint of obtaining high reliability. The thermal expansion coefficient of the first insulation layer 120 after curing is more preferably equal to or more than 20×10⁻⁶/K from the viewpoint of stress relaxation of the insulation material and obtaining a high-definition pattern.

The thickness of the first insulation layer 120 is not particularly limited, but is, for example, preferably equal to or less than 10 μm, more preferably equal to or less than 5 μm, and still more preferably equal to or less than 3 μm. When the thickness of the first insulation layer 120 is within the above-described range, fine wiring is easily formed in the first insulation layer 120. Note that the thickness of the first insulation layer 120 is preferably equal to or more than 1 μm from the viewpoint of insulation reliability.

[Step (b)]

Subsequently, when the first insulation layer 120 is formed, the surface of the first insulation layer 120 is modified, and a seed layer (not illustrated) is formed thereon. As a method for modifying the surface of the first insulation layer 120, a method such as desmear treatment, ultraviolet irradiation, electron beam irradiation, ozone water treatment, corona discharge treatment, or plasma treatment can be used. Among these methods, it is preferable to use ultraviolet irradiation or desmear treatment that does not require vacuum equipment and does not generate waste liquid or the like. Examples of the ultraviolet irradiation lamp used for modification include a high pressure mercury lamp, a low pressure mercury lamp, and a vacuum ultraviolet excimer lamp, and it is preferable to use the low pressure mercury lamp or the excimer lamp having a large activation effect. The modification by ultraviolet irradiation is preferably performed in the atmosphere, and more preferably performed in an oxygen atmosphere. The modification is preferably performed at 25° C. to 100° C. In order to further accelerate the reactivity, the temperature is more preferably from 40° C. to 100° C., and still more preferably from 60° C. to 100° C.

A seed layer is formed on the modified first insulation layer 120 by, for example, by electroless copper plating. In the present embodiment, first, in order to adsorb palladium serving as a catalyst for electroless copper plating onto the surface 121 of the first insulation layer 120, the first insulation layer 120 is washed with a pretreatment solution. The pretreatment solution may be a commercially available alkaline pretreatment solution containing sodium hydroxide or potassium hydroxide. The concentration of sodium hydroxide or potassium hydroxide is from 1% to 30%. The immersion time in the pretreatment solution is from 1 minute to 60 minutes. The immersion temperature in the pretreatment solution is from 25° C. to 80° C. After the pretreatment, washing may be performed with tap water, pure water, ultrapure water, or an organic solvent in order to remove excess pretreatment solution. Furthermore, the seed layer may be formed by sputtering. The seed layer formed by sputtering is preferably a metal species such as copper or titanium.

Palladium is deposited on the surface 121 of the first insulation layer 120 after immersion washing with an acidic aqueous solution. When the palladium is deposited, it is preferable to use a commercially available palladium-tin colloid solution, an aqueous solution containing palladium ions, a palladium ion suspension, or the like, and it is preferable to use an aqueous solution containing palladium ions which are effectively adsorbed onto a modification layer.

When immersing in an aqueous solution containing palladium ions, the temperature of the aqueous solution containing palladium ions is from 25° C. to 80° C., and the immersion time for adsorption is from 1 minute to 60 minutes. After the palladium ions are adsorbed, washing may be performed with tap water, pure water, ultrapure water, or an organic solvent in order to remove excess palladium ions. After the palladium ions are adsorbed, activation is performed to cause the palladium ions to act as a catalyst. As the reagent for activating the palladium ions, a commercially available activator (activation treatment solution) may be used. The temperature of the activator immersed to activate palladium ions is from 25° C. to 80° C., and the immersion time to activate the palladium ions is from 1 minute to 60 minutes. After the activation of palladium ions, washing may be performed with tap water, pure water, ultrapure water, or an organic solvent to remove excess activator.

Thereafter, electroless copper plating is performed on the surface 121 of the first insulation layer 120 to form a seed layer. This seed layer serves as a power supply layer for electroplating performed in step (e) and step (f) to be described later. Examples of the electroless copper plating include electroless pure copper plating (purity of 99 mass % or more) and electroless copper-nickel-phosphorus plating (nickel content: 1 mass % to 10 mass % and phosphorus content: 1 mass % to 13 mass %), but it is preferable to use the electroless copper-nickel-phosphorus plating from the viewpoint of adhesion. The electroless copper-nickel-phosphorus plating solution may be a commercially available plating solution, and for example, an electroless copper-nickel-phosphorus plating solution (trade name: “AISL-570” manufactured by JCU Corporation) can be used. The electroless copper-nickel-phosphorus plating is performed in an electroless copper-nickel-phosphorus plating solution at 60° C. to 90° C. The thickness of the seed layer formed by electroless copper plating is preferably from 80 nm to 700 nm, more preferably from 100 nm to 500 nm, and still more preferably from 150 nm to 300 nm.

[Step (c)]

Subsequently, when a seed layer is formed on the first insulation layer 120, as illustrated in (b) of FIG. 3, a resist layer 130 is formed on the first insulation layer 120 on which the seed layer is formed. The resist used here is a photosensitive resist, and the photosensitive resist is applied onto the seed layer on the first insulation layer 120 to form the resist layer 130. The thickness of the resist layer 130 is, for example, from 12 μm to 40 μm.

[Step (d)]

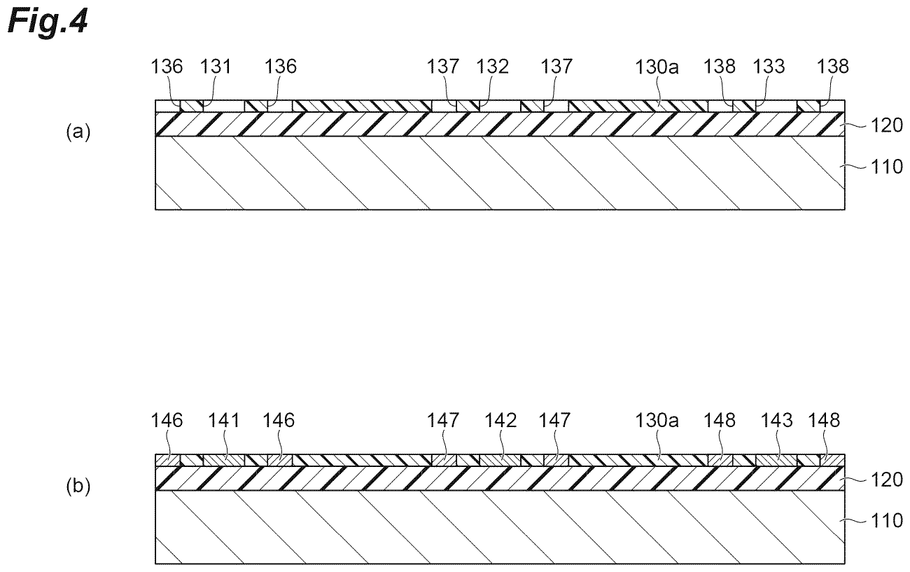

Subsequently, when the resist layer 130 is formed, as illustrated in (a) of FIG. 4, openings 131, 132, and 133 (first opening and second opening) for wiring electrodes and openings 136, 137, and 138 (third opening and fourth opening) for dummy electrodes are formed in the resist layer 130. Thus, a resist layer 130a provided with the openings is formed. The openings 131 to 133 respectively correspond to the wiring electrodes 71 to 73 described above (see FIG. 2). Each of the openings 131 to 133 has, for example, a circular or rectangular shape when viewed in plan. Furthermore, the openings 136 to 138 respectively correspond to the dummy electrodes 81 to 83 described above. Each of the openings 136 to 138 has, for example, a frame shape surrounding each of the openings 131 to 133 when viewed in plan, and has a circular void inside and a rectangular shape outside.

Examples of a method for forming the openings 131 to 133 for wiring electrodes and the openings 136 to 138 for dummy electrodes include laser ablation, photolithography, and imprinting. Among these methods, from the viewpoint of miniaturization and cost, it is preferable to form the resist layer 130 formed of a photosensitive resin material in step (c) and form the openings 131 to 133 by a photolithography process (exposure and development). As a method for exposing the photosensitive resin material, a normal projection exposure method, a contact exposure method, a direct drawing exposure method or the like can be used, and as a development method, it is preferable to use an alkaline aqueous solution of sodium carbonate or tetramethylammonium hydroxide (TMAH). After the openings 131 to 133 and the openings 136 to 138 are formed in the resist layer 130, the insulation material may be further heated and cured. The heating temperature is from 200° C. to 280° C., and the heating time is from 5 minutes to 1 hour. Furthermore, in a case where a residue of the resist layer 130 is present on the opened surface, the residue can be removed by oxygen plasma treatment, argon plasma treatment, or nitrogen plasma treatment.

The shape of the openings 131 to 133 for wiring electrodes formed in step (d) may be, for example, circular, elliptical, or rectangular. In this case, the diameter of the openings 131 to 133 may be from 5 μm to 400 μm, and the openings 131 to 133 may have a circular shape with a diameter of 5 μm to 10 μm in a finer case.

As described above, the openings 136 to 138 for dummy electrodes formed in step (d) have a frame shape surrounding the openings 131 to 133 for wiring electrodes (see FIG. 2). Therefore, at least a part of each of the openings 136 to 138 for dummy electrodes is formed so as to be located between two of the adjacent openings 131 to 133 for a wiring electrode. Note that the openings 136 to 138 for dummy electrodes may be formed simultaneously with the openings 131 to 133 for wiring electrodes, or may be formed separately.

[Step (e)]

Subsequently, as illustrated in (b) of FIG. 4, the wiring electrodes 141, 142, and 143 are formed in the openings 131 to 133 for wiring electrodes, respectively. In this step, copper plating is performed using the seed layer formed in step (b) as a power supply layer. Thus, the openings 131 to 133 in the resist layer 130a are filled with a conductive material (for example, copper), and the wiring electrodes 141 to 143 are formed. The thickness of the wiring electrodes 141 to 143 is preferably from 1 μm to 20 μm, more preferably 3 μm to 15 μm, and still more preferably 5 μm to 15 μm. Each of the wiring electrodes 141 to 143 has a planar shape corresponding to each of the openings 131 to 133, and the shape thereof is, for example, circular, elliptical, or rectangular.

[Step (f)]

Furthermore, dummy electrodes 146, 147, and 148 are respectively formed in the openings 136 to 138 for dummy electrodes together with step (e). In this step, similarly to step (e), copper plating is performed using the seed layer formed in step (b) as a power supply layer. Thus, the openings 136 to 138 are filled with a conductive material (for example, copper), and the dummy electrodes 146 to 148 are formed. The thickness of the dummy electrodes 146 to 148 is preferably from 1 μm to 20 μm, more preferably 3 μm to 15 μm, and still more preferably 5 μm to 15 μm. Each of the dummy electrodes 146 to 148 has a planar shape corresponding to each of the openings 136 to 138, and has, for example, a frame shape in which the inside is circular, elliptical, or rectangular and the outside is rectangular (see FIG. 2). However, the dummy electrodes 146 to 148 may have other shapes as long as a part of each of the dummy electrodes is located between two of the adjacent wiring electrodes 141 to 143, and the dummy electrodes 146 to 148 are only required to have a shape corresponding to or following the shape of the wiring electrodes 141 to 143. Note that the dummy electrodes 146 to 148 may be formed simultaneously with the wiring electrodes 141 to 143, or may be formed separately. That is, step (e) and step (f) may be performed simultaneously or separately.

[Step (g)]

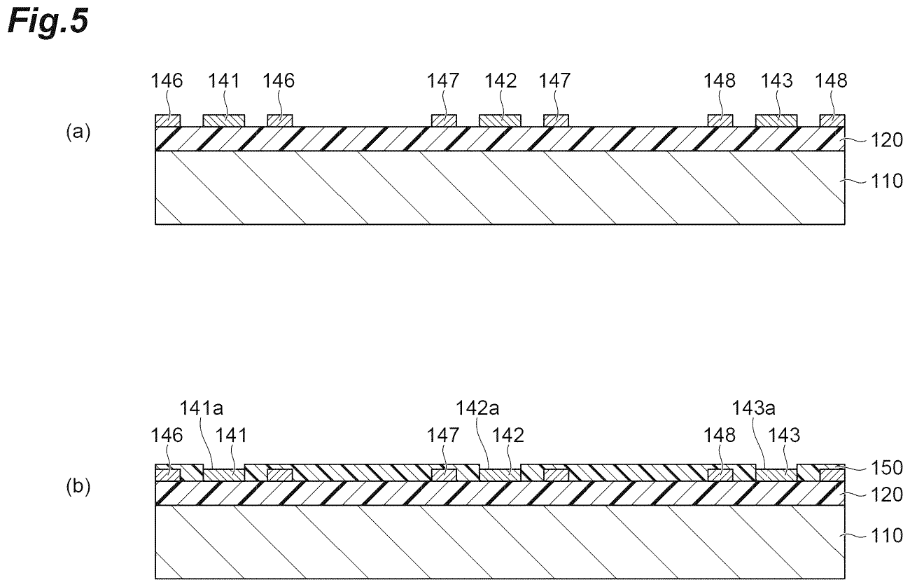

Subsequently, when the wiring electrodes 141 to 143 and the dummy electrodes 146 to 148 are formed, the resist layer 130a is removed as illustrated in (a) of FIG. 5. The removal of the resist layer 130a can be performed using various commercially available stripping solutions. Thereafter, the seed layer in a region exposed due to the removal of the resist layer 130a is removed. In addition to the removal of the seed layer, the palladium remaining under the seed layer may be removed. These may be removed using a commercially available removal solution (etching solution), and specific examples thereof include an acidic etching solution (BB-20, PJ-10, or SAC-700W3C, manufactured by JCU Corporation). Note that after the resist layer 130a is removed, a treatment for modifying the surfaces of the wiring electrodes 141 to 143 and the dummy electrodes 146 to 148, which are formed of a conductive material, may be performed. This treatment is, for example, a roughening treatment with acid, and the electrode surface can be roughened by this roughening treatment. As the treatment chemical, a commercially available treatment solution can be used.

[Step (h)]

Subsequently, when the resist layer 130a is removed, a second insulation layer 150 is formed on the first insulation layer 120 so as to cover the wiring electrodes 141 to 143 and the dummy electrodes 146 to 148. The second insulation layer 150 is made of a photosensitive resin material, a solder resist, or the like, and the thickness of the second insulation layer 150 may be, for example, from 15 μm to 30 μm. When the second insulation layer 150 is formed, as illustrated in (b) of FIG. 5, the respective surfaces 141a, 142a, and 143a of the wiring electrodes 141 to 143 are formed so as to be exposed from the second insulation layer 150. As this exposure method, a lithography process or laser processing can be used. As the lithography process, a semi-additive method or a subtractive process can be used. Note that the thickness of the dummy electrodes 146 to 148 embedded in the second insulation layer 150 is preferably half or more of the thickness of the second insulation layer 150.

The material used for the second insulation layer 150 may be, for example, a material containing a carboxyl group-containing photosensitive resin composition. This carboxyl group-containing photosensitive resin composition may be a carboxyl group-containing photosensitive resin obtained by reacting acrylic acid and/or methacrylic acid (c) with a phenolic compound (a), which is obtained by a condensation reaction of a polymethylol compound of bisphenol A or bisphenol F with a phenol, contains a structure of the following general formula (1) and has two or more phenolic hydroxyl groups in a molecule, wherein part or the whole of the phenolic hydroxyl groups being modified in an oxyalkyl groups, and by further reacting a polybasic acid anhydride (d) with the resultant reaction product.

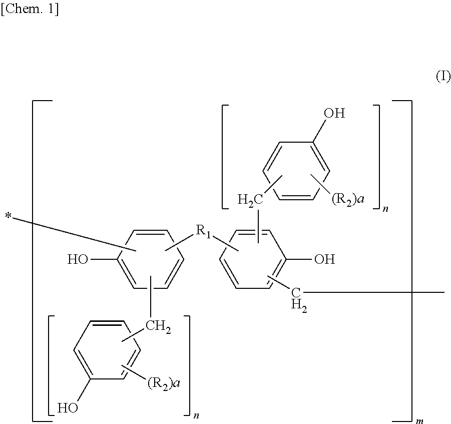

(In the formula, R1 represents —C(CH₃)₂— or —CH₂—, R₂ represents a hydrocarbon group having 1 to 11 carbon atoms, a represents an integer of 0 to 3, n represents an integer of 1 to 2, and m represents an integer of 1 to 10.)

As described above, the wiring board 30 constituting the semiconductor device 1 illustrated in FIG. 1 can be manufactured.

### (Method for Manufacturing Semiconductor Device)

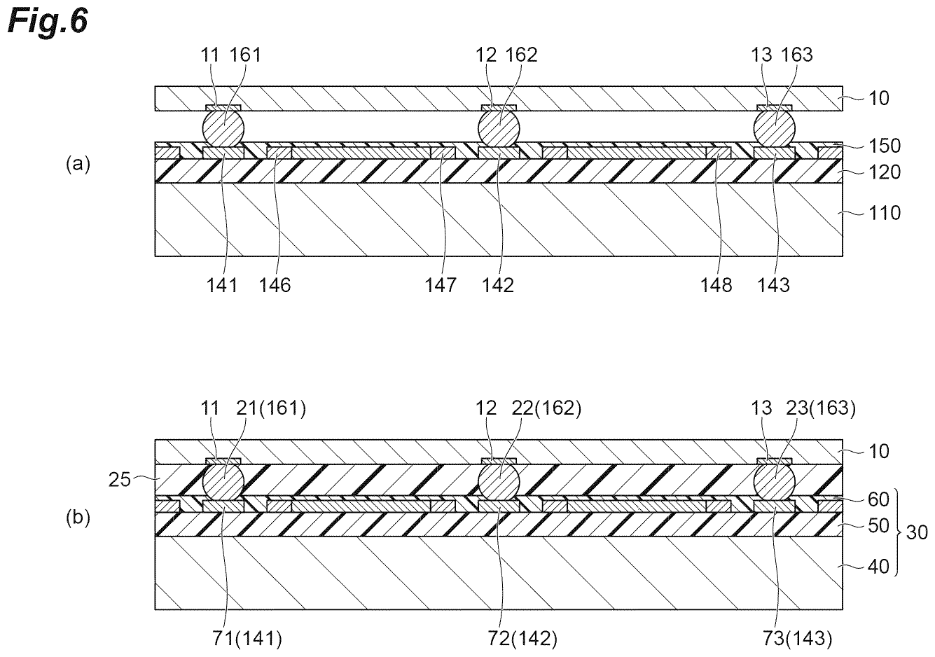

Next, a method for manufacturing the semiconductor device 1 using the wiring board 30 manufactured by the above-described manufacturing method will be described with reference to FIG. 6. FIG. 6 is a view illustrating a method for manufacturing the semiconductor device 1. The method for manufacturing the semiconductor device 1 includes the following steps (j) to (k).
(j) A step of preparing the wiring board 30 described above.
(k) A step of mounting a semiconductor chip on the wiring board using a conductive member.
   [Step (j)]

In step (j), as illustrated in (a) of FIG. 6, the wiring board 30 is first prepared. Furthermore, one or more semiconductor chips 10 are prepared.

[Step (k)]

Subsequently, when the preparation of the wiring board 30 is completed, the semiconductor chip 10 is mounted on the wiring board 30. In this mounting step, first, the surface treatment of the wiring electrodes 141 to 143 of the wiring board 30 is performed to remove the organic component on the exposed surfaces. Thereafter, solder bumps 161, 162, and 163 (a first conductive member and a second conductive member) are respectively disposed (mounted) on the wiring electrodes 141 to 143 of the wiring board 30 to perform reflow treatment. Thereafter, the semiconductor chip 10 is mounted on the solder bumps 161 to 163, and the reflow treatment is performed again. Thus, connection terminals 11 to 13 of the semiconductor chip 10 are respectively connected to the wiring electrodes 141 to 143 via the solder bumps 161 to 163, and the semiconductor chip 10 is mounted on the surface of the wiring board 30 on which the dummy electrodes 146 to 148 are formed.

Subsequently, when the reflow treatment is completed, singulation is performed by dicing, and thereafter, as illustrated in (b) of FIG. 6, an underfill material, which is the insulation resin layer 25, is filled between the second insulation layer 60 (corresponding to the second insulation layer 150 before singulation) of the wiring board 30 and the semiconductor chip 10 to perform encapsulating, thereby forming the insulation resin layer 25. Thus, the semiconductor device 1 illustrated in FIG. 1 is manufactured.

As described above, according to the method for manufacturing the wiring board according to the present embodiment, a part of each of the dummy electrodes 146 to 148 (dummy electrodes 81 to 83) not connected to the semiconductor chip 10 or the like is located between two of the wiring electrodes 141 to 143 (two of the wiring electrodes 71 to 73) connected to the semiconductor chip 10 or the like. Thus, in the wiring board 30 manufactured by this manufacturing method, it is possible to suppress the occurrence of cracks in the second insulation layer 60 etc. or to suppress the extension of the cracks that occur. As a result, when the semiconductor device 1 is manufactured using the wiring board 30, the wiring of the wiring electrodes 141 to 143 (wiring electrodes 71 to 73) is prevented from being fractured due to a temperature change. As described above, in the method for manufacturing this wiring board, it is possible to provide a wiring board in which the breakage of wiring due to cracks is prevented.

In the method for manufacturing the wiring board according to the present embodiment, the width of each of the dummy electrodes 146 to 148 (dummy electrodes 81 to 83) is equal to or more than 10 μm in a direction extending outward from the center of each of the wiring electrodes 141 to 143 (wiring electrodes 71 to 73). Thus, the dummy electrodes 146 to 148 (dummy electrodes 81 to 83) can reliably suppress the extension of the cracks occurring in the insulation layer in the vicinity of the wiring electrodes 141 to 143 (wiring electrodes 71 to 73).

In the method for manufacturing the wiring board according to the present embodiment, the dummy electrodes 146 to 148 (dummy electrodes 81 to 83) respectively have portions 81c, 82c, and 83c each having a maximum width of 100 μm or more in a direction extending outward from the center of each of the wiring electrodes 141 to 143 (wiring electrodes 71 to 73). Thus, the occurrence of cracks in the insulation layer in the vicinity of the wiring electrodes 141 to 143 (wiring electrodes 71 to 73) can be reliably suppressed, or the extension of the cracks that occur can be more reliably suppressed.

In the method for manufacturing the wiring board according to the present embodiment, a distance between the respective wiring electrodes 141 to 143 (wiring electrodes 71 to 73) and the dummy electrodes 146 to 148 (dummy electrodes 81 to 83) is equal to or more than 50 μm. Thus, insulation between the respective wiring electrodes 141 to 143 (wiring electrodes 71 to 73) and the dummy electrodes 146 to 148 (dummy electrodes 81 to 83) is ensured, and a wiring board in which the dummy electrodes 146 to 148 (dummy electrodes 81 to 83) do not interfere with the conduction performance of the wiring electrodes 141 to 143 (wiring electrodes 71 to 73) can be obtained.

The method for manufacturing the wiring board according to the present embodiment may further include a step of forming a wiring portion 90 between the dummy electrodes 146 to 148 (dummy electrodes 81 to 83) adjacent to each other. The wiring portion 90 may have a plurality of wirings of 10 μm or less. In this case, it is possible to provide a wiring board in which a desired wiring is formed between the adjacent wiring electrodes 141 to 143 (wiring electrodes 71 to 73).

In the method for manufacturing the wiring board according to the present embodiment, the dummy electrodes 146 to 148 (dummy electrodes 81 to 83), which are adjacent to each other, may be connected by a conductive material. Thus, the strength of the dummy electrodes 146 to 148 (dummy electrodes 81 to 83) can be improved to provide a wiring board that more reliably suppresses the occurrence of cracks in the vicinity of the wiring electrodes 141 to 143 (wiring electrodes 71 to 73).

In the method for manufacturing the wiring board according to the present embodiment, the dummy electrodes 146 to 148 (dummy electrodes 81 to 83) are respectively formed so as to surround the wiring electrodes 141 to 143 (wiring electrodes 71 to 73) when viewed in plan. Thus, it is possible to provide the wiring board 30 in which the occurrence of cracks or the extension of cracks is suppressed in any direction in the vicinity of the wiring electrodes 141 to 143 (wiring electrodes 71 to 73). Furthermore, by respectively providing the dummy electrodes 146 to 148 (dummy electrodes 81 to 83) so as to surround the wiring electrodes 141 to 143 (wiring electrodes 71 to 73), it is possible to provide the wiring board 30 having an arrangement that does not interfere with improvement in the mounting density of the wiring electrodes 141 to 143 (wiring electrodes 71 to 73).

In the method for manufacturing the wiring board according to the present embodiment, the wiring electrodes 141 to 143 (wiring electrodes 71 to 73) may have a curved portion when viewed in plan, and for example, the outer periphery has a circular shape. Furthermore, the dummy electrodes 146 to 148 (dummy electrodes 81 to 83) may have a curved portion when viewed in plan, and for example, the inner periphery has a circular shape. Since the wiring electrodes 141 to 143 (wiring electrodes 71 to 73) have the curved portion, the occurrence of cracks starting from the vicinity of the wiring electrodes 141 to 143 (wiring electrodes 71 to 73) can be suppressed. Furthermore, since the dummy electrodes 146 to 148 (dummy electrodes 81 to 83) have the curved portion, it is possible to disperse the force of the cracks that occur and suppress further extension of the cracks.

In the method for manufacturing the wiring board according to the present embodiment, the dummy electrodes 146 to 148 (dummy electrodes 81 to 83) have a thickness that is half or more of the thickness of the second insulation layer 60. Thus, the dummy electrodes 146 to 148 (dummy electrodes 81 to 83) can reliably suppress the extension of the cracks starting from the vicinity of the wiring electrodes 141 to 143 (wiring electrodes 71 to 73).

In the method for manufacturing the semiconductor device according to the present embodiment, in the wiring board 30 on which the semiconductor chip 10 is mounted, it is possible to provide a semiconductor device in which the occurrence of cracks starting from the vicinity of the wiring electrodes 71 to 73 is suppressed or the extension of the cracks that occur is suppressed. Thus, it is possible to provide a semiconductor device in which breakage of wiring due to cracks is prevented.

In the wiring board according to the present embodiment, at least a part of each of the dummy electrodes 81 to 83 not connected to the semiconductor chip 10 or the like is located between two of the wiring electrodes 71 to 73 connected to the semiconductor chip 10 or the like. In this case, even when a temperature change or the like occurs in the semiconductor device 1 that uses the wiring board 30, the occurrence of cracks in the second insulation layer 60 or the like can be suppressed, or the extension of the cracks that occur can be suppressed. As a result, in the semiconductor device 1 that uses the wiring board 30, the wiring of the wiring electrodes 71 to 73 is prevented from being fractured due to the temperature change.

In the wiring board according to the present embodiment, the width of each of the dummy electrodes 81 to 83 is equal to or more than 10 μm in a direction extending outward from the center of each of the wiring electrodes 71 to 73. Thus, the dummy electrodes 81 to 83 can reliably suppress the extension of the cracks occurring in the insulation layer in the vicinity of the wiring electrodes 71 to 73. Thus, it is possible to more reliably prevent breakage of the wiring due to the cracks.

In the wiring board according to the present embodiment, the dummy electrodes 81 to 83 are formed so as to respectively surround the wiring electrodes 71 to 73 when viewed in plan. Thus, it is possible to suppress the occurrence of cracks or the extension of cracks in any direction in the vicinity of the wiring electrodes 71 to 73. Furthermore, by respectively providing the dummy electrodes 81 to 83 so as to surround the wiring electrodes 71 to 73, it is possible to provide the wiring board 30 having an arrangement that does not interfere with improvement in the mounting density of the wiring electrodes 71 to 73.

### EXAMPLE

Hereinafter, the present invention will be described more specifically with reference to an example. However, the present invention is not limited to these examples.

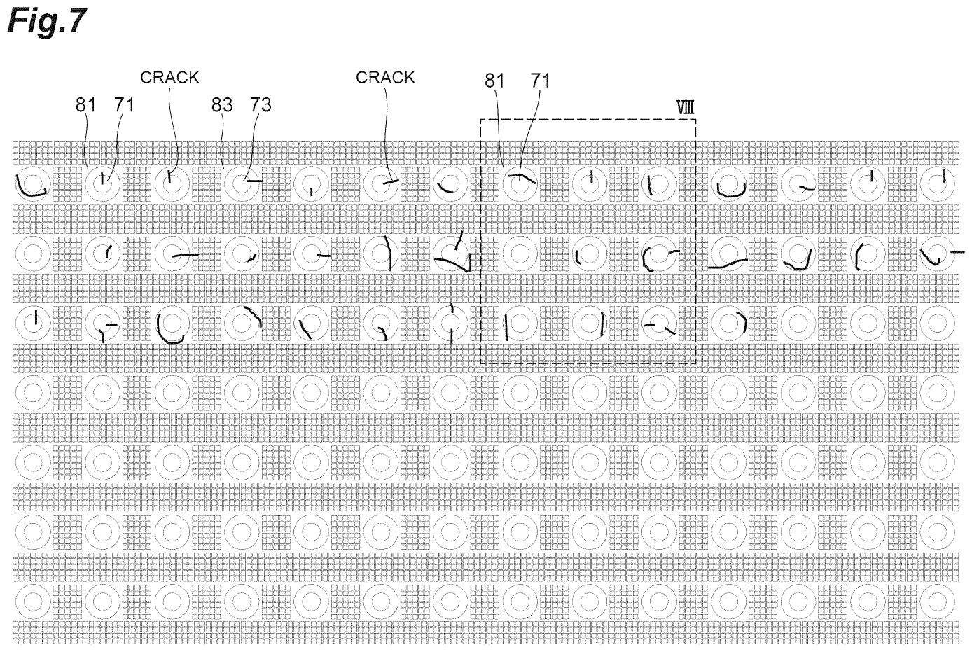

First, as illustrated in FIG. 7, a large sample corresponding to a plurality of the wiring boards 30 was prepared. This sample was prepared by the method illustrated in FIGS. 3 to 5 described above, and the wiring electrodes 141 to 143 (wiring electrodes 71 to 73) and the dummy electrodes 146 to 148 (dummy electrodes 81 to 83) were manufactured by copper plating. The diameter of each of the wiring electrodes 71 to 73 was from 240 μm to 280 μm. The width of each of the dummy electrodes 81 to 83 (minimum width, the width corresponding to the portion 81b in FIG. 2) was 150 μm in a direction extending outward from the center of the corresponding wiring electrode. Furthermore, the width of each of the dummy electrodes 81 to 83 (maximum width, the width corresponding to each of the portions 81c, 82c, and 83c in FIG. 2) was 170 μm in a direction extending outward from the center of the corresponding wiring electrode. Furthermore, as the second insulation layer 150 (second insulation layer 60), a photosensitive insulation material was used, and the thickness was 18 μm. As illustrated in (b) of FIG. 5, the wiring electrodes 141 to 143 (wiring electrodes 71 to 73) were exposed from the surface of the second insulation layer 150, but the dummy electrodes 146 to 148 (dummy electrodes 146 to 148) were not exposed from the surface of the second insulation layer 150. As other materials and manufacturing methods, conventional materials and manufacturing methods were used. A sample of the semiconductor package manufactured in this manner was subjected to a temperature cycle test. The test temperature was changed from −65° C. to 150° C., and the holding times at the time of reaching the maximum temperature and the time of reaching the minimum temperature were respectively set to 15 minutes.

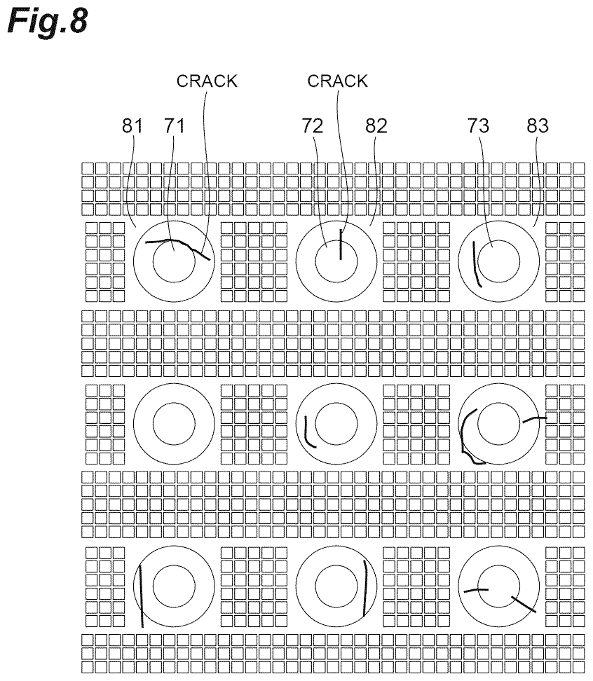

FIGS. 7 and 8 illustrate the results of the state of cracks that occurred when the wiring board 30 was actually manufactured and the above-described test was performed. FIG. 8 was an enlarged view of a portion VIII in FIG. 7. According to this test result, it was found that even in a case where cracks occurred in the vicinity of the wiring electrodes 71 to 73, further extension of cracks was suppressed by the dummy electrodes 81 to 83 located between the wiring electrodes 71 to 73. As described above, it could be confirmed that by providing the dummy electrodes, the extension of the cracks was suppressed, and the breakage of the wiring due to the cracks was prevented.

### REFERENCE SIGNS LIST

1 Semiconductor Device
10 Semiconductor Chip
11 to 13 Connection Terminals
21 to 23 Solder Bumps (First Conductive Portion and Second Conductive Portion)
25 Insulation Resin Layer
30 Wiring Board
40, 110 Support Substrate
50, 120 First Insulation Layer
60, 150 Second Insulation Layer
71 to 73, 141 to 143 Wiring Electrodes (First Wiring Electrode and Second Wiring Electrode)
81 to 83, 146 to 148 Dummy Electrodes (First Dummy Electrode and Second Dummy Electrode)
90 Wiring Portion
130 Resist Layer
131 to 133 Openings (First Opening and Second Opening)
136 to 138 (Third Opening and Fourth Opening) 141a to 143a Surface

1. A method for manufacturing a wiring board, the method comprising:
forming a first insulation layer on a support substrate;
forming a resist layer on the first insulation layer;
forming a plurality of openings including a first opening and second opening for wiring electrodes and a third opening for a dummy electrode in the resist layer;
forming a first wiring electrode and a second wiring electrode in the first opening and the second opening, respectively;
forming a first dummy electrode in the third opening;
removing the resist layer after forming the first wiring electrode, the second wiring electrode, and the first dummy electrode; and
forming a second insulation layer on the first insulation layer so as to cover at least the first dummy electrode,
wherein surfaces of the first wiring electrode and the second wiring electrode are exposed from the second insulation layer, and at least a part of the first dummy electrode is located between the first wiring electrode and the second wiring electrode.

2. The method for manufacturing a wiring board according to claim 1,
wherein a width of the first dummy electrode is equal to or more than 10 μm in a direction extending outward from a center of the first wiring electrode.

3. The method for manufacturing a wiring board according to claim 1,
wherein the first dummy electrode has a portion having a maximum width of 100 μm or more in a direction extending outward from a center of the first wiring electrode.

4. The method for manufacturing a wiring board according to claim 1,
wherein a distance between the first wiring electrode and the first dummy electrode is equal to or more than 50 μm.

5. The method for manufacturing a wiring board according to claim 1, further comprising:
further forming a fourth opening for a dummy electrode in the forming the plurality of openings in the resist layer; and
forming a second dummy electrode in the fourth opening,
wherein at least a part of each of the first dummy electrode and the second dummy electrode is formed between the first wiring electrode and the second wiring electrode, the first dummy electrode is located on the first wiring electrode side, and the second dummy electrode is located on the second wiring electrode side.

6. The method for manufacturing a wiring board according to claim 5, further comprising:
forming a wiring portion between the first dummy electrode and the second dummy electrode, the wiring portion including a plurality of wirings of 10 μm or less.

7. The method for manufacturing a wiring board according to claim 5,
wherein the first dummy electrode and the second dummy electrode are connected by a conductive material.

8. The method for manufacturing a wiring board according to claim 1,
wherein the first dummy electrode is formed so as to surround the first wiring electrode when viewed in plan.

9. The method for manufacturing a wiring board according to claim 1,
wherein the first wiring electrode has a curved portion when viewed in plan, and the first dummy electrode has a curved portion when viewed in plan.

10. The method for manufacturing a wiring board according to claim 1,
wherein the first dummy electrode has a thickness that is half or more of a thickness of the second insulation layer.

11. A method for manufacturing a semiconductor device, the method comprising:
preparing the wiring board manufactured by the method for manufacturing a wiring board according to claim 1; and
mounting a semiconductor chip on the wiring board using a conductive member.

12. The method for manufacturing a semiconductor device according to claim 11,
wherein in the mounting the semiconductor chip, a first conductive member and a second conductive member, which are the conductive member, are disposed on the first wiring electrode and second wiring electrode of the wiring board, respectively, the semiconductor chip is mounted on the first conductive member and the second conductive member, connection terminals of the semiconductor chip are connected to the first wiring electrode and the second wiring electrode via the first conductive member and the second conductive member, respectively, and the semiconductor chip is mounted on a surface of the wiring board on which the first dummy electrode is formed.

13. A wiring board comprising:
a support substrate;
a first insulation layer placed on the support substrate;
a second insulation layer placed on the first insulation layer;
a first wiring electrode and second wiring electrode placed in the second insulation layer; and
a first dummy electrode placed in the second insulation layer,
wherein surfaces of the first wiring electrode and the second wiring electrode are exposed from the second insulation layer, and at least a part of the first dummy electrode is located between the first wiring electrode and the second wiring electrode.

14. The wiring board according to claim 13,
wherein a width of the first dummy electrode is equal to or more than 10 μm in a direction extending outward from a center of the first wiring electrode.

15. The wiring board according to claim 13, further comprising:
a second dummy electrode placed in the second insulation layer,
wherein at least a part of each of the first dummy electrode and the second dummy electrode is located between the first wiring electrode and the second wiring electrode, the first dummy electrode is located on the first wiring electrode side, and the second dummy electrode is located on the second wiring electrode side.

16. The wiring board according to claim 13,
wherein the first dummy electrode is formed so as to surround the first wiring electrode when viewed in plan.

17. A semiconductor device comprising:
the wiring board according to claim 13;
a first conductive portion and second conductive portion placed on the wiring board and on the first wiring electrode and the second wiring electrode, respectively; and
a semiconductor chip mounted on the second insulation layer via the first conductive portion and the second conductive portion
